(19) United States
(12) Patent Application Publication
(10) Pub. No.: US 2026/0353581 A1
(43) Pub. Date: Nov. 5, 2026

(54) SYSTEMS AND METHODS FOR PREVENTING DAMAGE DURING INSERTION OF INFORMATION HANDLING RESOURCE WITH A PIN-LOCKING MECHANISM

(71) Applicant: Dell Products L.P., Round Rock, TX (US)

(72) Inventors: Yayun LIU, Austin, TX (US); Michael LO, Round Rock, TX (US)

(73) Assignee: Dell Products L.P., Round Rock, TX (US)

(21) Appl. No.: 19/198,264

(22) Filed: May 5, 2025

(51) Int. Cl. H05K 7/14; G06F 1/183

(52) U.S. Cl. CPC H05K 7/1402; G06F 1/183

(57) ABSTRACT

A receptacle connector configured to electrically and mechanically couple to an information handling resource may include a latch configured to mechanically engage with the information handling resource when the information handling resource is inserted into the receptacle connector and a pin-locking mechanism housed substantially within the receptacle connector. The pin-locking mechanism may be mechanically coupled to the latch and configured to when the latch is in an open position for receiving the information handling resource into the receptacle connector, cause a pin of the pin-locking mechanism to occupy space adjacent to the receptable connector, and when the latch is in a closed position for maintaining the information handling resource in the receptacle connector, cause the pin of the pin-locking mechanism to retract within the receptacle connector.

### TECHNICAL FIELD

The present disclosure relates in general to information handling systems, and more particularly to preventing damage during insertion of an information handling resource, such as a memory module, into a receptacle connector by restricting access between adjacent receptacle connectors with a pin-locking mechanism.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Information handling systems may often use one or more circuit boards. A circuit board may comprise a substrate of a plurality of conductive layers separated and supported by layers of insulating material laminated together, with conductive traces disposed on and/or in any of such conductive layers, with vias for coupling conductive traces of different layers together, and with pads for coupling electronic components (e.g., packaged integrated circuits, slot connectors, etc.) to conductive traces of the circuit board.

A type of circuit board often used in information handling systems is a memory module, such as a dual-inline memory module (DIMM). DIMMs typically comprise a circuit board with a plurality of memory chips mounted thereon. A DIMM may include an edge connector on an edge of the circuit board used to implement the DIMM, the edge connector configured to mechanically and electrically couple to a receptacle connector, which may also be referred to as a socket.

To accommodate receipt of multiple memory modules in an information handling system, the information handling system may include a plurality of closely-spaced receptacle connectors. However, in many implementations, a volume of empty space may exist between adjacent receptacle connectors. The existence of such volume of empty space presents a risk of accidental installation of a memory module into this volume of empty space, which could potentially damage the memory module or one or both of the adjacent receptacle connectors. Accordingly, systems and methods may be desired to mitigate or eliminate such risk.

### SUMMARY

In accordance with the teachings of the present disclosure, the disadvantages and problems associated with inserting an information handling resource into a connector of an information handling system may be reduced or eliminated.

In accordance with embodiments of the present disclosure, an information handling system may include a circuit board and a plurality of receptacle connectors electrically coupled to and mechanically mounted upon the circuit board, wherein a receptacle connector of the plurality of receptacle connectors comprises a latch configured to mechanically engage with an information handling resource inserted into the receptacle connector and a pin-locking mechanism housed substantially within the receptacle connector. The pin-locking mechanism may be mechanically coupled to the latch and configured to when the latch is in an open position for receiving the information handling resource into the receptacle connector, cause a pin of the pin-locking mechanism to occupy space between the receptacle connector and a second receptacle connector of the plurality of receptacle connectors adjacent to the receptable connector, and when the latch is in a closed position for maintaining the information handling resource in the receptacle connector, cause the pin of the pin-locking mechanism to retract within the receptacle connector.

In accordance with these and other embodiments of the present disclosure, a receptacle connector configured to electrically and mechanically couple to an information handling resource may include a latch configured to mechanically engage with the information handling resource when the information handling resource is inserted into the receptacle connector and a pin-locking mechanism housed substantially within the receptacle connector. The pin-locking mechanism may be mechanically coupled to the latch and configured to when the latch is in an open position for receiving the information handling resource into the receptacle connector, cause a pin of the pin-locking mechanism to occupy space adjacent to the receptable connector, and when the latch is in a closed position for maintaining the information handling resource in the receptacle connector, cause the pin of the pin-locking mechanism to retract within the receptacle connector.

In accordance with these and other embodiments of the present disclosure, a method for forming a receptacle connector configured to electrically and mechanically couple to an information handling resource may include configuring a latch of the receptacle connector to mechanically engage with the information handling resource when the information handling resource is inserted into the receptacle connector, housing a pin-locking mechanism substantially within the receptacle connector, and mechanically coupling the pin-locking mechanism to the latch such that when the latch is in an open position for receiving the information handling resource into the receptacle connector, a pin of the pin-locking mechanism occupies space adjacent to the receptable connector, and when the latch is in a closed position for maintaining the information handling resource in the receptacle connector, the pin of the pin-locking mechanism retracts within the receptacle connector.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a block diagram of an example information handling system, in accordance with embodiments of the present disclosure;

FIG. 2 illustrates an isometric perspective view of an example memory slot, in accordance with embodiments of the present disclosure;

FIG. 3 illustrates a side elevation view of a portion of the example memory slot of FIG. 2, in accordance with embodiments of the present disclosure;

FIG. 4A illustrates selected components of a pin-locking mechanism of the example memory slot of FIGS. 2 and 3 in a deactivated position of the pin-locking mechanism, in accordance with embodiments of the present disclosure;

FIG. 4B illustrates a side elevation view of a portion of the example memory slot of FIGS. 2 and 3 in a deactivated position of the pin-locking mechanism, in accordance with embodiments of the present disclosure;

FIG. 4C illustrates a top-down plan view of two adjacent memory slots in a deactivated position of the pin-locking mechanism, in accordance with embodiments of the present disclosure;

FIG. 5A illustrates selected components of a pin-locking mechanism of the example memory slot of FIGS. 2 and 3 in an activated position of the pin-locking mechanism, in accordance with embodiments of the present disclosure;

FIG. 5B illustrates a side elevation view of a portion of the example memory slot of FIGS. 2 and 3 in an activated position of the pin-locking mechanism, in accordance with embodiments of the present disclosure; and

FIG. 5C illustrates a top-down plan view of two adjacent memory slots in an activated position of the pin-locking mechanism, in accordance with embodiments of the present disclosure.

### DETAILED DESCRIPTION

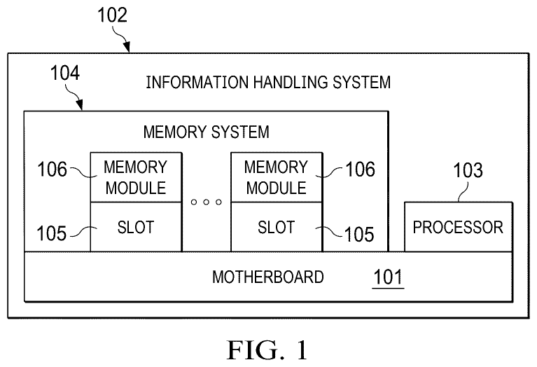

Preferred embodiments and their advantages are best understood by reference to FIGS. 1 through 5C, wherein like numbers are used to indicate like and corresponding parts.

For the purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a PDA, a consumer electronic device, a network storage device, or any other suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

For the purposes of this disclosure, computer-readable media may include any instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory; as well as communications media such as wires, optical fibers, microwaves, radio waves, and other electromagnetic and/or optical carriers; and/or any combination of the foregoing.

For the purposes of this disclosure, information handling resources may broadly refer to any component system, device or apparatus of an information handling system, including without limitation processors, buses, memories, I/O devices and/or interfaces, storage resources, network interfaces, motherboards, integrated circuit packages; electro-mechanical devices (e.g., air movers), displays, and power supplies.

For the purposes of this disclosure, circuit boards may broadly refer to printed circuit boards (PCBs), printed wiring boards (PWBs), printed wiring assemblies (PWAs), etched wiring boards, and/or any other board or similar physical structure operable to mechanically support and electrically couple electronic components (e.g., packaged integrated circuits, slot connectors, etc.). A circuit board may comprise a substrate of a plurality of conductive layers separated and supported by layers of insulating material laminated together, with conductive traces disposed on and/or in any of such conductive layers, with vias for coupling conductive traces of different layers together, and with pads for coupling electronic components (e.g., packaged integrated circuits, slot connectors, etc.) to conductive traces of the circuit board.

FIG. 1 illustrates a block diagram of selected components of an example information handling system 102, in accordance with embodiments of the present disclosure. In some embodiments, information handling system 102 may be a personal computer. In some embodiments, information handling system 102 may comprise or be an integral part of a server. In other embodiments, information handling system 102 may be a portable information handling system (e.g., a laptop, notebook, tablet, handheld, smart phone, personal digital assistant, etc.). As shown in FIG. 1, information handling system 102 may include a motherboard 101, a processor 103 electrically and mechanically coupled to motherboard 101, and a memory system 104 electrically and mechanically coupled to motherboard 101, thus electrically coupling memory system 104 to processor 103.

Motherboard 101 may include a circuit board configured to provide structural support for one or more information handling resources of information handling system 102 and/or electrically couple one or more of such information handling resources to each other and/or to other electric or electronic components external to information handling system 102.

Processor 103 may include any system, device, or apparatus configured to interpret and/or execute program instructions and/or process data, and may include, without limitation, a microprocessor, microcontroller, digital signal processor (DSP), application specific integrated circuit (ASIC), or any other digital or analog circuitry configured to interpret and/or execute program instructions and/or process data. In some embodiments, processor 103 may interpret and/or execute program instructions and/or process data stored in memory system 104 and/or another component of information handling system 102.

Memory system 104 may be communicatively coupled to processor 103 and may include any system, device, or apparatus configured to retain program instructions and/or data for a period of time (e.g., computer-readable media). Memory system 104 may include RAM, EEPROM, a PCMCIA card, flash memory, magnetic storage, opto-magnetic storage, or any suitable selection and/or array of volatile or non-volatile memory that retains data after power to information handling system 102 is turned off.

As shown in FIG. 1, memory system 104 may comprise a plurality of memory slots 105, each mechanically and electrically coupled to motherboard 101 and each configured to receive a corresponding memory module 106. A memory slot 105 may include any system, device, or apparatus configured to receive a memory module 106 in order to electrically couple such memory module 106 to processor 103. Each memory module 106 may include any system, device or apparatus configured to retain program instructions and/or data for a period of time (e.g., computer-readable media). Each memory module 106 may include a dynamic random access memory (DRAM) module (e.g, a Dual In-line Package (DIP) memory, a Single In-line Pin Package (SIPP) memory, a Single In-line Memory Module (SIMM), a Dual In-line Memory Module (DIMM), a Ball Grid Array (BGA)), or any other suitable memory.

To insert a memory module 106 into a memory slot 105, a person may need to apply force along an edge of the memory module and in a direction perpendicular to a surface of the circuit board implementing the memory module 106, in order to cause an edge connector of the memory module 106 to electrically and mechanically couple to the memory slot 105, which may be implemented as a receptacle connector. However, as described in the Background section, during such attempted insertion of a memory module 106 into a memory slot 105, the memory module 106 may be accidentally inserted into a volume of space between adjacent memory slots 105, presenting a risk of damage to such memory module 106 or adjacent memory slots 105.

In addition to motherboard 101, processor 103, and memory system 104, information handling system 102 may include one or more other information handling resources.

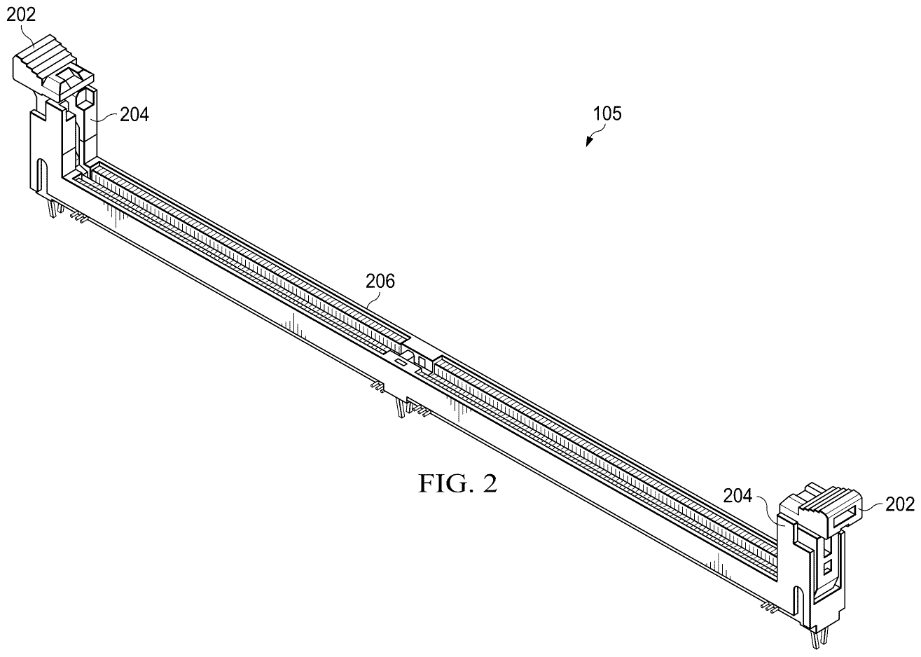

FIG. 2 illustrates an isometric perspective view of an example memory slot 105, in accordance with embodiments of the present disclosure. As shown in FIG. 2, memory slot 105 may include a housing 206 configured to receive an edge connector of a memory module 106 and having a plurality of pins, wherein each pin of the plurality of pins is configured to electrical couple to a corresponding pin of the edge connector of such memory module 106. Module support towers 204 may rise vertically from opposite ends of housing 206, and may include features to aid in retention of a memory module 106 within housing 206.

Further, memory slot 105 may include latches 202, wherein each latch 202 is mechanically coupled to a respective module support tower 204. Each latch 202 may be coupled to its respective module support tower 204 via an axis, allowing each latch 202 to rotate between a closed position and an open position relative to its respective module support tower 204. Each latch 202 may also include mechanical features configured to aid in the extraction of a memory module 106 from housing 206 when such latch 202 is in the open position and configured to aid in retention of a memory module 106 within housing 206 when such latch 202 is in the closed position.

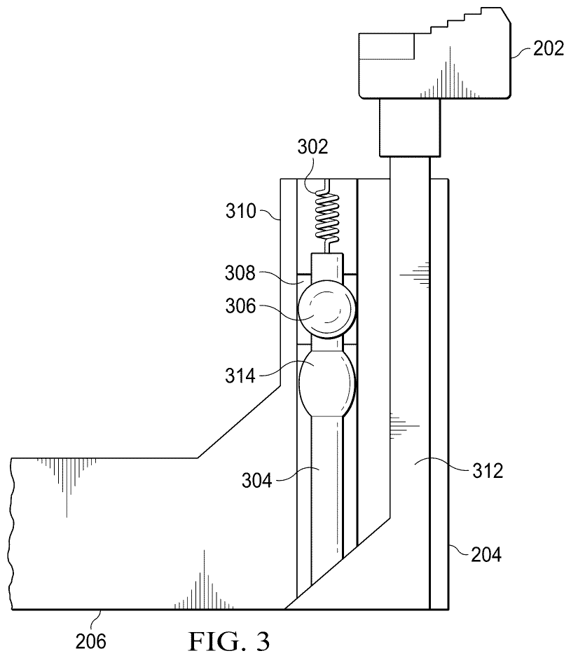

FIG. 3 illustrates a side elevation view of a portion of memory slot 105, in accordance with embodiments of the present disclosure. In particular, FIG. 3 depicts one end of memory slot 105, including a latch 202, module support tower 204, and a portion of housing 206. Further, module support tower 204 is depicted as transparent in FIG. 3 in order to depict a pin-locking mechanism that may reside within module support tower 204. As shown in FIG. 3, such pin-locking mechanism may include an internal spring 302, an internal spindle 304, a pin 306, a pin cartridge 308, and a pin shaft 310.

Internal spring 302 may be mechanically coupled between a top of the inside of module support tower 204 and a top of internal spindle 304. In operation, internal spring 302 may be configured to generate a spring force between the top of the inside of module support tower 204 and the top of internal spindle 304 in order to bias internal spindle 304 towards a lower position within module support tower 204 in the absence of a force applied to a bottom of internal spindle 304 by an extractor 312 mechanically coupled to latch 202.

Internal spindle 304 may be mechanically coupled at its top to internal spring 302, and may be sized and shaped (e.g., “slide-shaped”) to mechanically engage with extractor 312, such that internal spindle 304 may move vertically up and down within module support tower 204 in response to mechanical motion of latch 202 (e.g., moving up within module support tower 204 when latch 202 is moved from its closed position to its open position and moving down within module support tower 204 when latch 202 is moved from its open position to its closed position). As also shown in FIG. 3, a portion 314 of internal spindle 304 may be bell-shaped or have another suitable shape configured to mechanically interact when the pin-locking mechanism is activated, in order to push pin 306 out of module support tower 204, as described in greater detail below.

Pin 306 may comprise any suitable mechanical component that may mechanically interact with internal spindle 304, such that when latch 202 is in its open position, pin 306 may extend from module support tower 204 in order to create a mechanical interference that physically blocks space between adjacent memory slots 105, thus preventing insertion of a memory module 106 in the space between such adjacent memory slots 105. Further, pin 306 may mechanically interact with internal spindle 304, such that when latch 202 is in its closed position, pin 306 may retract within module support tower 204, leaving the space between such adjacent memory slots 105 open to allow for airflow. Pin 306 may be constructed from metal, plastic, or any other suitable material.

Pin shaft 310 may be positioned vertically within module support tower 204 (or in some embodiments, may form an outer wall of module support tower 204) and parallel with internal spindle 304 and may include pin cartridge 308 formed therein as an empty space within pin shaft 310. Thus, pin cartridge 308 may form a housing that enables pin 306 to retract within module support tower 204 when latch 202 is in its closed position.

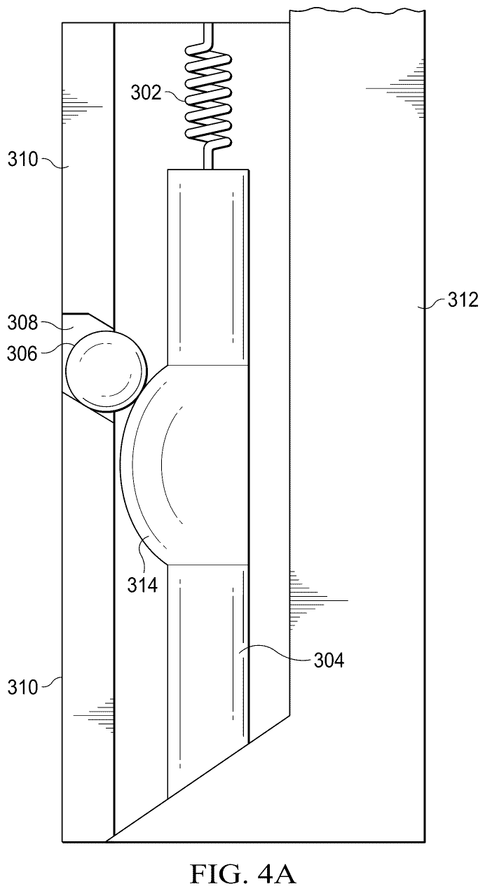

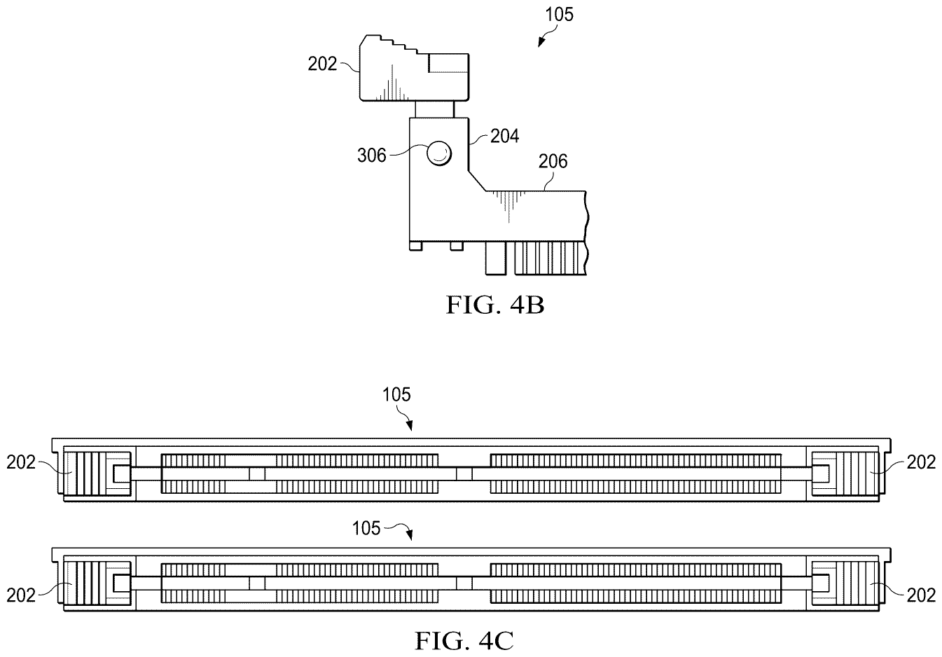

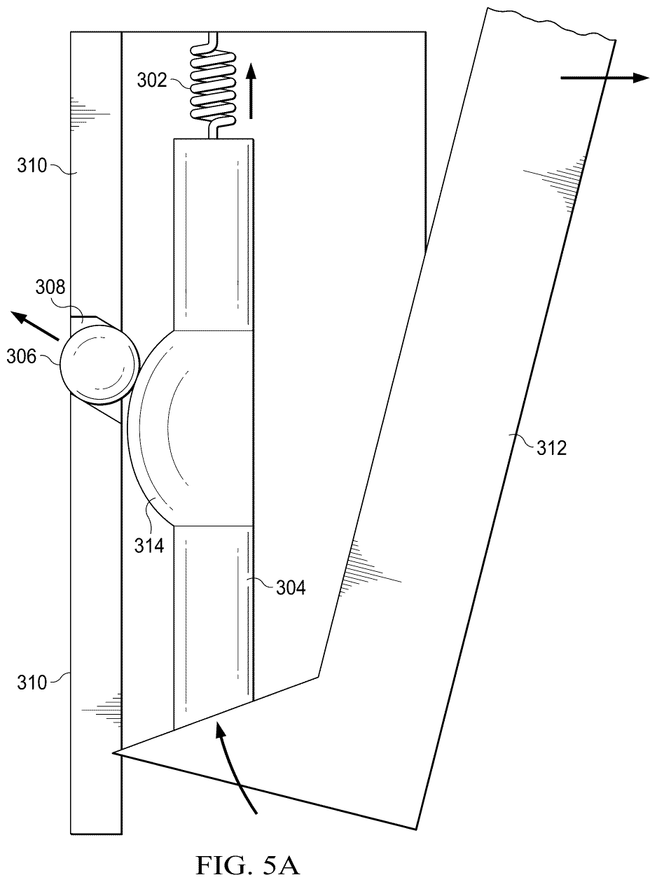

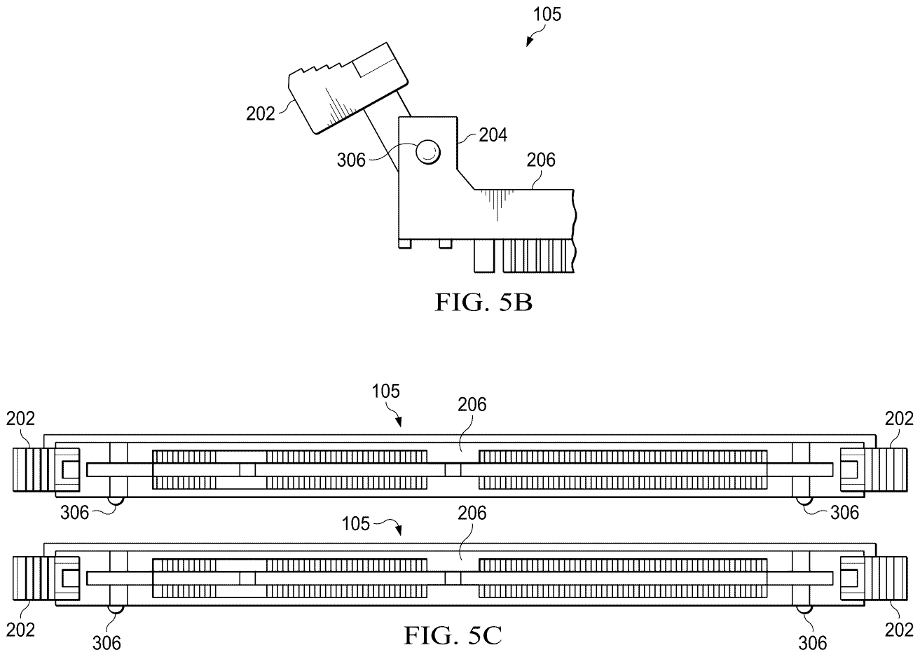

In operation, as described in greater detail below, movement of pin 306 may correspond to changes in a position of latch 202. For example, as latch 202 is moved from its closed position to its open position, latch 202 may mechanically interact with extractor 312, which may in turn mechanically interact with internal spindle 304, which may in turn mechanically interact (e.g., via portion 314) with pin 306 such that pin 306 moves outward (i.e., toward a viewer of FIG. 3) into the space between adjacent memory slots 105. Likewise, as latch 202 is moved from its open position to its closed position, internal spring 302 may force internal spindle 304 downward, causing pin 306 to move inward (i.e., away from a viewer of FIG. 3) as it retracts back into pin cartridge 308 (e.g., under the force of gravity). Such activation and deactivation of pin 306 is further described below with reference to FIGS. 4A-5B.

FIG. 4A illustrates selected components of a pin-locking mechanism of memory slot 105 in a deactivated position of the pin-locking mechanism, in accordance with embodiments of the present disclosure. Notably, for purposes of exposition, FIG. 4A combines both side and front views (e.g., side views of extractor 312 similar to that in FIG. 3, but front views parallel with the direction of housing 206 for the other components shown in FIG. 4A). The actual movement of pin 306 may be perpendicular to the direction of motion of extractor 312.

FIG. 4B illustrates a side elevation view of a portion of memory slot 105 in a deactivated position of the pin-locking mechanism, in accordance with embodiments of the present disclosure. FIG. 4C illustrates a top-down plan view of two adjacent memory slots 105 in a deactivated position of the pin-locking mechanism, in accordance with embodiments of the present disclosure.

As shown in FIGS. 4A-4C, when latch 202 is in its closed position, with extractor 312 standing vertically, pin 306 may retract into cartridge 308 (e.g., due to gravity). In such configuration, memory slots 105 may appear as standard slots, unobstructed by additional components, as seen in FIG. 4C.

FIG. 5A illustrates selected components of a pin-locking mechanism of memory slot 105 in an activated position of the pin-locking mechanism, in accordance with embodiments of the present disclosure. Notably, for purposes of exposition, FIG. 5A combines both side and front views (e.g., side views of extractor 312 similar to that in FIG. 3, but front views parallel with the direction of housing 206 for the other components shown in FIG. 5A). The actual movement of pin 306 may be perpendicular to the direction of motion of extractor 312.

FIG. 5B illustrates a side elevation view of a portion of memory slot 105 in a deactivated position of the pin-locking mechanism, in accordance with embodiments of the present disclosure. FIG. 5C illustrates a top-down plan view of two adjacent memory slots 105 in a deactivated position of the pin-locking mechanism, in accordance with embodiments of the present disclosure.

As shown in FIGS. 5A-5C, when latch 202 is in its open position, extractor 312 may mechanically interact with internal spindle 304, pushing it upward and compressing internal spring 302. Such upward motion of internal spindle 304 may cause portion 314 to mechanically interact with pin 306, pushing pin 306 outward from pin cartridge 308. With pin 306 extended in such configuration, pin 306 may create a barrier between adjacent memory slots 105 (e.g., as shown in FIG. 5C), thus preventing insertion of a memory module 106 into the space between memory slots 105.

While the terms “top,” “bottom,” “front,” “back,” and “side” are used for purposes of exposition and clarity, such terms are not intended to limit any of the components disclosed herein to a particular orientation or configuration.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described above, the principles of the present disclosure may be implemented using any number of techniques, whether currently known or not. The present disclosure should in no way be limited to the exemplary implementations and techniques illustrated in the figures and described above.

Unless otherwise specifically noted, articles depicted in the figures are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

What is claimed is:

1. An information handling system comprising:
a circuit board; and
a plurality of receptacle connectors electrically coupled to and mechanically mounted upon the circuit board, wherein a receptacle connector of the plurality of receptacle connectors comprises:
a latch configured to mechanically engage with an information handling resource inserted into the receptacle connector; and
a pin-locking mechanism housed substantially within the receptacle connector, the pin-locking mechanism mechanically coupled to the latch and configured to:
when the latch is in an open position for receiving the information handling resource into the receptacle connector, cause a pin of the pin-locking mechanism to occupy space between the receptacle connector and a second receptacle connector of the plurality of receptacle connectors adjacent to the receptable connector; and
when the latch is in a closed position for maintaining the information handling resource in the receptacle connector, cause the pin of the pin-locking mechanism to retract within the receptacle connector.

2. The information handling system of claim 1, wherein the receptacle connector further comprises:
a housing for receiving the information handling resource; and
a module support tower mechanically coupled between the housing and the latch, wherein the pin-locking mechanism is housed substantially within the module support tower.

3. The information handling system of claim 2, wherein the pin-locking mechanism comprises an internal spindle mechanically coupled to the latch and configured to move vertically within the module support tower responsive to movement of the latch, wherein the internal spindle comprises a mechanical feature configured to mechanically engage with the pin to cause the pin to occupy space between the receptacle connector and the second receptacle connector when the latch is in the open position.

4. The information handling system of claim 3, wherein a top of the internal spindle is mechanically coupled to a top of an inside of the module support tower via a spring biased to mechanically force the internal spindle and the top of the inside of the module support tower apart.

5. The information handling system of claim 3, wherein the pin-locking mechanism comprises a pin shaft substantially parallel to the internal spindle and comprising a pin cartridge for housing the pin when the latch is in the closed position and the pin is retracted within the receptacle connector.

6. The information handling system of claim 5, wherein a wall of the module support tower comprises the pin shaft.

7. The information handling system of claim 1, wherein the receptacle connector is a memory slot configured to receive a memory module.

8. A receptacle connector configured to electrically and mechanically couple to an information handling resource, the receptacle connector comprising:
a latch configured to mechanically engage with the information handling resource when the information handling resource is inserted into the receptacle connector; and
a pin-locking mechanism housed substantially within the receptacle connector, the pin-locking mechanism mechanically coupled to the latch and configured to:
when the latch is in an open position for receiving the information handling resource into the receptacle connector, cause a pin of the pin-locking mechanism to occupy space adjacent to the receptable connector; and
when the latch is in a closed position for maintaining the information handling resource in the receptacle connector, cause the pin of the pin-locking mechanism to retract within the receptacle connector.

9. The receptacle connector of claim 8, further comprising:
a housing for receiving the information handling resource; and
a module support tower mechanically coupled between the housing and the latch, wherein the pin-locking mechanism is housed substantially within the module support tower.

10. The receptacle connector of claim 9, wherein the pin-locking mechanism comprises an internal spindle mechanically coupled to the latch and configured to move vertically within the module support tower responsive to movement of the latch, wherein the internal spindle comprises a mechanical feature configured to mechanically engage with the pin to cause the pin to occupy space between the receptacle connector and the second receptacle connector when the latch is in the open position.

11. The receptacle connector of claim 10, wherein a top of the internal spindle is mechanically coupled to a top of an inside of the module support tower via a spring biased to mechanically force the internal spindle and the top of the inside of the module support tower apart.

12. The receptacle connector of claim 10, wherein the pin-locking mechanism comprises a pin shaft substantially parallel to the internal spindle and comprising a pin cartridge for housing the pin when the latch is in the closed position and the pin is retracted within the receptacle connector.

13. The receptacle connector of claim 12, wherein a wall of the module support tower comprises the pin shaft.

14. The receptacle connector of claim 8, wherein the receptacle connector is a memory slot configured to receive a memory module.

15. A method for forming a receptacle connector configured to electrically and mechanically couple to an information handling resource, the method comprising:
configuring a latch of the receptacle connector to mechanically engage with the information handling resource when the information handling resource is inserted into the receptacle connector;
housing a pin-locking mechanism substantially within the receptacle connector; and
mechanically coupling the pin-locking mechanism to the latch such that:
when the latch is in an open position for receiving the information handling resource into the receptacle connector, a pin of the pin-locking mechanism occupies space adjacent to the receptable connector; and
when the latch is in a closed position for maintaining the information handling resource in the receptacle connector, the pin of the pin-locking mechanism retracts within the receptacle connector.

16. The method of claim 15, wherein the receptacle connector further comprises a housing for receiving the information handling resource and a module support tower mechanically coupled between the housing and the latch, and the method further comprising housing the pin-locking mechanism substantially within the module support tower.

17. The method of claim 16, further comprising mechanically coupling an internal spindle of the pin-locking mechanism comprising an internal spindle to the latch, such that the internal spindle is configured to move vertically within the module support tower responsive to movement of the latch, wherein the internal spindle comprises a mechanical feature configured to mechanically engage with the pin to cause the pin to occupy space between the receptacle connector and the second receptacle connector when the latch is in the open position.

18. The method of claim 17, further comprising mechanically coupling a top of the internal spindle to a top of an inside of the module support tower via a spring biased to mechanically force the internal spindle and the top of the inside of the module support tower apart.

19. The method of claim 17, further comprising forming a pin shaft within the pin-locking mechanism such that the pin shaft is substantially parallel to the internal spindle and such that a pin cartridge houses the pin when the latch is in the closed position and the pin is retracted within the receptacle connector.

20. The method of claim 19, wherein a wall of the module support tower comprises the pin shaft.
